(19) United States
(12) Patent Application Publication
(10) Pub. No.: US 2015/0028385 A1
(43) Pub. Date: Jan. 29, 2015

(54) LATERAL BIPOLAR TRANSISTOR AND ITS MANUFACTURING METHOD

(71) Applicant: Hitachi, Ltd., Tokyo (JP)

(72) Inventors: Tomoyuki Miyoshi, Tokyo (JP); Takayuki Ooshima, Tokyo (JP); Youhei Yanagida, Tokyo (JP)

(73) Assignee: Hitachi, Ltd.

(21) Appl. No.: 14/445,576

(22) Filed: Jul. 29, 2014

(30) Foreign Application Priority Data
Jul. 29, 2013 (JP) 2013-156250

(51) Int. Cl. H01L 29/739; H01L 29/08; H01L 29/10; H01L 29/66

(52) U.S. Cl. CPC H01L 29/7394; H01L 29/66325; H01L 29/0821; H01L 29/0808; H01L 29/1008
USPC 257/141; 438/135

(57) ABSTRACT

The disclosed lateral bipolar transistor is manufactured by a manufacturing process of self-alignedly implanting an impurity to a gate electrode and thermally diffusing the impurity to form a base layer and an emitter layer. The gate electrode is utilized as an independent fourth terminal in addition to base, emitter, and collector terminals, whereby hfe can be controlled and enhanced by a gate potential. Accordingly, the present invention can provide a bipolar transistor that is hardly affected by a manufacturing variation, or that can be corrected by the gate terminal, and that has a high gain.

### CROSS-REFERENCE TO RELATED APPLICATION

This application claims the priority of Japanese Patent Application No. 2013-156250 filed Jul. 29, 2013, which is incorporated herein by reference in its entity.

### BACKGROUND OF THE INVENTION

1. Field of the Invention

The present invention relates to a lateral bipolar transistor, and its manufacturing method, and more particularly to a structure of a lateral bipolar transistor and its manufacturing method.

2. Description of the Related Art

Examples of an element forming a switching circuit include a bipolar transistor. FIGS. 1A and 1B illustrates an example of a switching circuit controlling a load. When the load is controlled by drawing current, an NPN bipolar transistor 4 illustrated in FIG. 1A is employed. When the load is controlled by flowing current, a PNP bipolar transistor 8 illustrated in FIG. 1B is employed. An advantage of employing the bipolar transistor is to enable a flow of large collector current Ic with a small input signal Ib. Recently, an electric vehicle is a subject to which this circuit is applied, for example, and a transistor that drives a large load has been demanded. Since a power supply supplying power has a high voltage, high breakdown voltage characteristic is also required. It is also significant, from the viewpoint of reducing cost, whether or not a level shifter outputting a pulse and a logical circuit can be mounted together with the bipolar transistor.

In order to meet these needs, semiconductor companies have developed an element with a lateral structure on which a high breakdown DMOSFET and a bipolar transistor can be mounted together, based upon a process of a microfabricated CMOSFET that can operate with high speed, in order to reduce cost. A bipolar transistor has also been formed such that collector, base, and emitter terminals can be drawn on a surface of a semiconductor substrate, in order that the bipolar transistor can be mounted together with other elements.

FIG. 2 illustrates a sectional structure of the bipolar transistor described in JP 2012-129297 A. An N-type collector layer 11 having high concentration is formed at a deep part of an N-type collector drift layer 19 included in a semiconductor substrate. A P-type base layer 10 is formed above the N-type collector layer 11 via the drift layer 19 having low concentration, and an N-type emitter layer 9 is formed above the P-type base layer 10. All of these layers are connected to a collector electrode 17, a base electrode 16, and an emitter electrode 15, which are exposed on the substrate surface, and an NPN bipolar transistor 20 formed in the substrate can control these layers through the electrodes formed on the substrate surface.

However, in this structure, a base region having a deeper distribution than an emitter region is formed by using a photomask different from a photomask for the emitter region. Therefore, it is considered that the variation in the position of the photomask affects the variation in the effective base concentration of the bipolar transistor that is formed in the perpendicular direction. The relationship between the base concentration and the amplification factor hfe of the bipolar transistor is as represented by a mathematical formula 1.

$$\begin{matrix}[ Mathematical Formula 1 ] & \\ hfe = \frac{1}{\frac{{Wb}^{2}}{{Lb}^{2}} + \frac{Dp}{Dn} \frac{Nb}{Ne} \frac{Wb}{Le}} & ( Mathematical Formula 1 )\end{matrix}$$

In this formula, Wb is a base width, Lb is an electron diffusion length, Dp is a diffusion coefficient of a hole, Dn is a diffusion coefficient of an electron, Nb is a base concentration, and Ne is an emitter concentration.

The amplification factor hfe depends upon the base concentration. Therefore, this structure has a variation factor that is the position of the photomask to the amplification factor hfe during the manufacturing process.

As a technique of forming an impurity region on a semiconductor surface with a stable concentration and diffusion length, JP 2010-251624 A describes a technique of implanting an impurity with a gate electrode self-alignment manufacturing method.

FIG. 3 is a partial sectional view illustrating a manufacturing method described in JP 2010-251624 A.

A P-type impurity is self-alignedly implanted, as indicated by 25, to a gate electrode 22. After the P-type impurity is diffused by thermal load, an N-type impurity is similarly self-alignedly implanted, as indicated by 27, to the gate electrode 22. With this process, a P-type impurity region 26 formed below the gate is formed to have constant diffusion length and concentration. An application of this invention is a lateral LDMOSFET. This invention describes that the effect of this invention is to obtain a stable Vth and reduce cost. This invention does not describe an application to a bipolar transistor. The present inventors consider that a high hfe performance can be stably obtained by applying this partial manufacturing method to an emitter/base region of a bipolar transistor, particularly to a portion where a base is to be formed.

### SUMMARY OF THE INVENTION

The present invention aims to provide a lateral bipolar transistor that can be mounted together with a micro CMOSFET and LDMOSFET, and that can provide a stable hfe performance with a small manufacturing variation, and to provide its manufacturing method.

A lateral bipolar transistor according to the present invention includes a semiconductor substrate; and a gate oxide film and a gate electrode, which are formed on a surface of the semiconductor substrate; a collector region formed apart from the gate electrode with a distance and having a feed region of a first conductive type; an emitter region formed in the vicinity of the gate oxide film on the opposite side of the collector region across the gate electrode and having a feed region of a first conductive type; and a base region of a second conductive type formed below the gate oxide film so as to enclose the emitter region and having a feed region located close to the emitter feed region. Desirably, an impurity concentration of the collector region, the base region, and the emitter region becomes smaller in the order from the collector region, the base region, and the emitter region, below the gate oxide film in the vicinity of the surface of the semiconductor.

According to the present invention, a bipolar transistor having a stable high hfe performance can be realized by a process which can allow the bipolar transistor to be mounted together with a microfabricated CMOSFET and LDMOSFET.

The hfe value can be controlled by supplying a certain fixed voltage to the gate electrode. Accordingly, when the bipolar transistor is incorporated into a feedback circuit and controlled by the gate electrode, a circuit having a stable gain and corrected variation in the manufacturing factors can be realized. Consequently, a high-quality application circuit can be provided.

### BRIEF DESCRIPTION OF THE DRAWINGS

FIGS. 1A and 1B are diagrams illustrating a universal circuit including a bipolar transistor;

FIG. 2 is a diagram illustrating a structure of a bipolar transistor including a prior art;

FIGS. 3A and 3B are diagrams illustrating a gate self-alignment process including a prior art;

FIG. 4 is a plan view illustrating a device structure of a lateral bipolar transistor according to a first embodiment of the present invention;

FIG. 5 is a sectional view illustrating the device structure of the lateral bipolar transistor according to the first embodiment of the present invention;

FIG. 6 is a sectional view illustrating an impurity profile, calculated by a process simulation, of the lateral bipolar transistor according to the first embodiment of the present invention;

FIG. 7 is a chart illustrating a detailed concentration distribution at an NPN junction of the lateral bipolar transistor according to the first embodiment of the present invention, wherein the concentration distribution is calculated by a process simulation;

FIG. 8 is a sectional view illustrating an electron current density profile, calculated by a device simulation, of the lateral bipolar transistor according to the first embodiment of the present invention;

FIGS. 9A to 9F are process flows illustrating a manufacturing method of a lateral bipolar transistor according to a second embodiment of the present invention;

FIG. 10 is a plan view illustrating a device structure of a lateral bipolar transistor according to a third embodiment of the present invention;

FIG. 11 is a sectional view illustrating the device structure of the lateral bipolar transistor according to the third embodiment of the present invention;

FIG. 12 is a sectional view illustrating an impurity profile, calculated by a process simulation, of the lateral bipolar transistor according to the third embodiment of the present invention;

FIG. 13 is a chart illustrating a detailed concentration distribution at an NPN junction of the lateral bipolar transistor according to the third embodiment of the present invention, wherein the concentration distribution is calculated by a process simulation;

FIG. 14 is a sectional view illustrating an electron current density profile, calculated by a device simulation, of the lateral bipolar transistor according to the third embodiment of the present invention;

FIGS. 15A to 15H are process flows illustrating a manufacturing method of a lateral bipolar transistor according to a fourth embodiment of the present invention;

FIG. 16 is a process flow illustrating a manufacturing method of a lateral bipolar transistor according to a fifth embodiment of the present invention;

FIG. 17 is a chart illustrating hfe-Vg dependency, calculated by a device simulation, of the lateral bipolar transistor according to the fifth embodiment of the present invention;

FIG. 18 is a diagram illustrating a change in an electron density caused by an application of Vg in the lateral bipolar transistor according to the fifth embodiment of the present invention, wherein the electron density is calculated by a device simulation;

FIG. 19 is a chart illustrating a detailed change in an electron density caused by an application of Vg in the lateral bipolar transistor according to the fifth embodiment of the present invention, wherein the electron density is calculated by a device simulation; and

FIG. 20 is a schematic diagram illustrating an application circuit of the lateral bipolar transistor according to the fifth embodiment of the present invention.

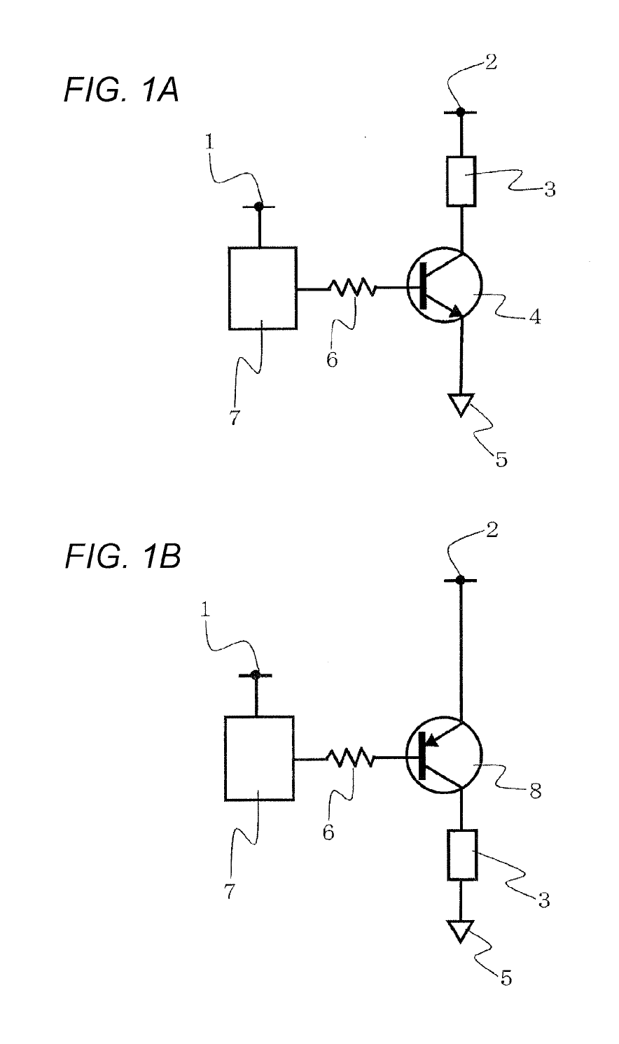

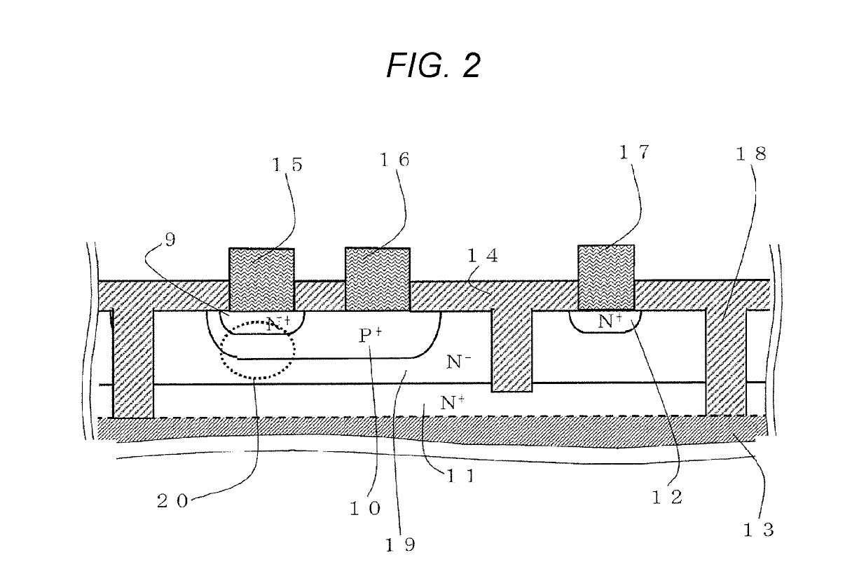

### DESCRIPTION OF THE PREFERRED EMBODIMENTS

Preferred embodiments of the present invention will be described in detail below with reference to the accompanying drawings. A conductive type in the description below is only illustrative, and even if an N-type and a P-type in each of embodiments are inversed, the similar effect can be expected.

### First Embodiment

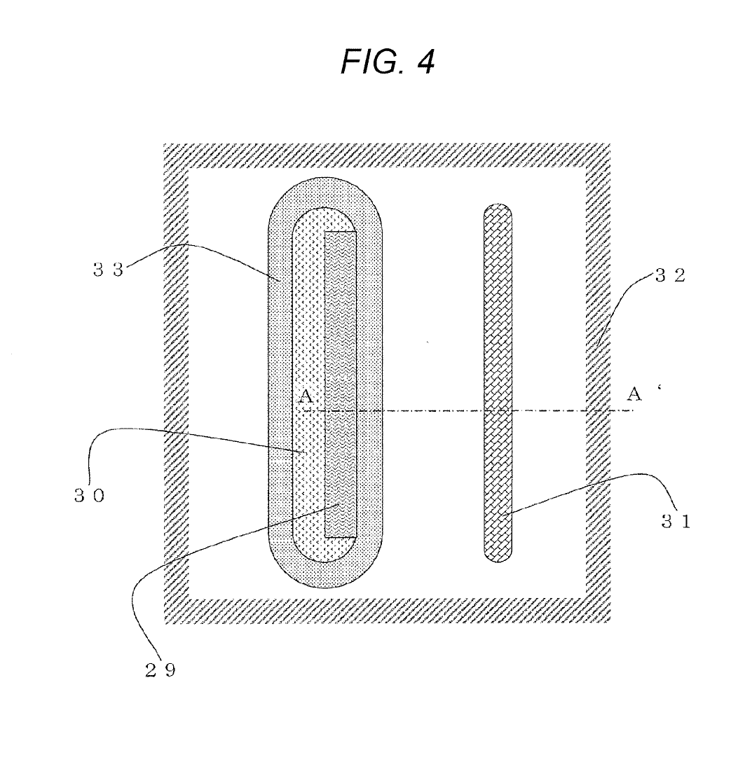

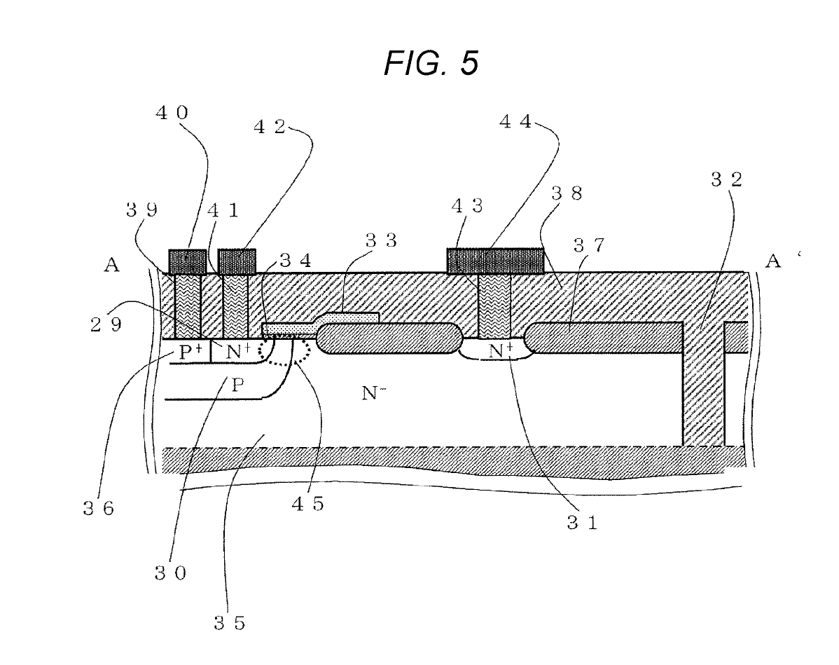

FIG. 4 is a plan view illustrating a device structure of a lateral bipolar transistor according to a first embodiment of the present invention, and FIG. 5 is a sectional view (sectional view taken along a line A-A′ in FIG. 4) illustrating the device structure of the lateral bipolar transistor according to the first embodiment of the present invention.

A field oxide film 37, a gate oxide film 34, and a gate electrode 33 are selectively formed on a surface of a semiconductor substrate having an N-type drift layer 35. An impurity is implanted through the gate electrode 33 and is thermally diffused, whereby a P-type base layer 30 is self-alignedly formed. Similarly, an impurity is implanted in a region, shallower than the base region, on the semiconductor surface via the gate electrode 33 and is thermally diffused, whereby an emitter feed layer 29 is self-alignedly formed. A base feed layer 36 is formed at a position contacting the emitter feed layer 29. A collector feed layer 31 is also formed at the side opposite to this region across the field oxide film 37.

A base electrode 40 is formed on the base feed layer 36 via a base plug 39, an emitter electrode 42 is formed on the emitter feed layer 29 via an emitter plug 41, and a collector electrode 44 is formed on the collector feed layer 31 via a collector plug 43. Thus, a lateral bipolar transistor to which the present invention is applied is formed.

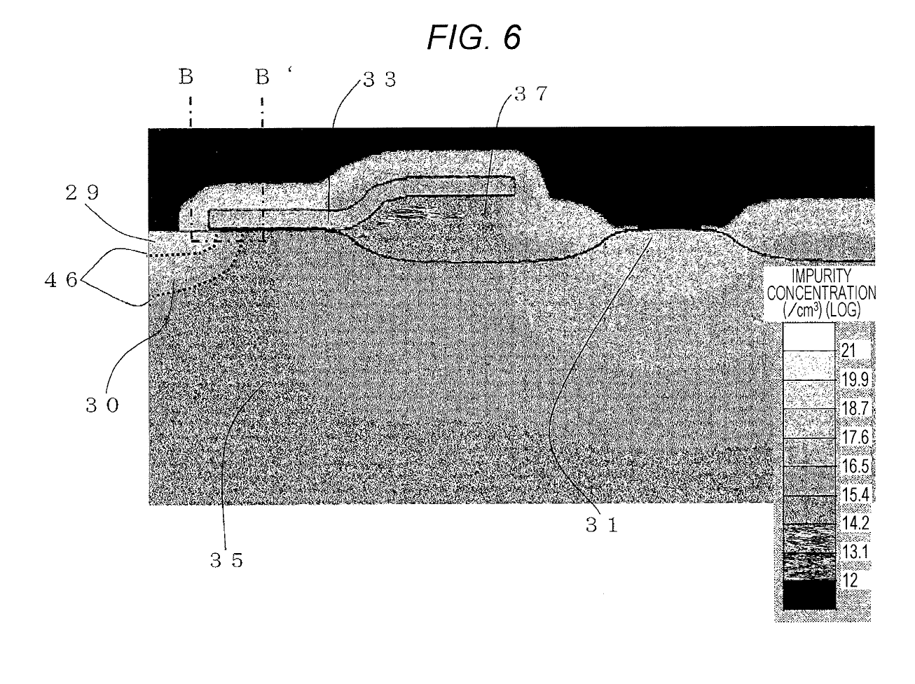

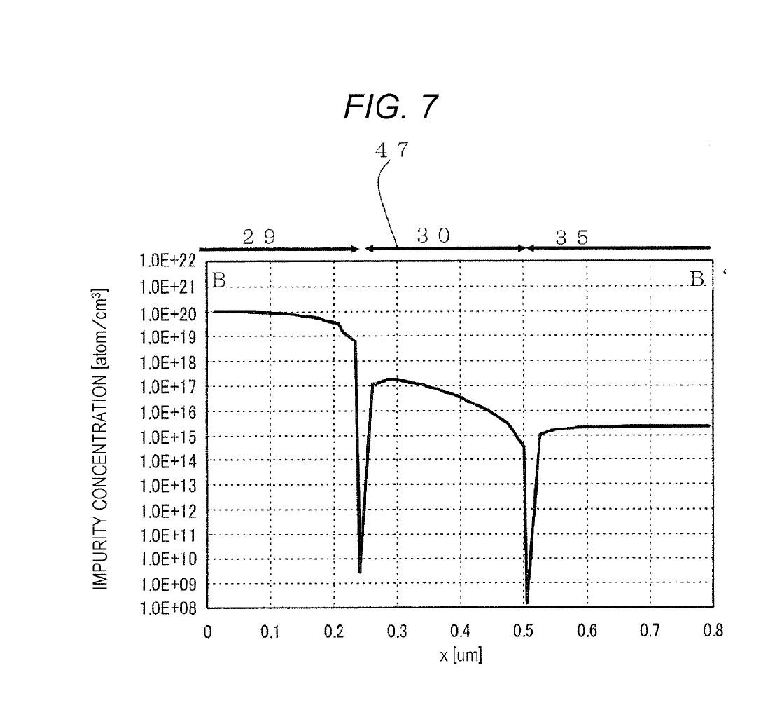

FIG. 6 illustrates a sectional structure of a lateral bipolar transistor, which is formed by a process simulation and to which the present invention is applied. Boron is self-alignedly implanted to the gate electrode 33 with acceleration energy of 30 keV and impurity concentration of 5E13 atom/cm², and is thermally diffused, whereby the P-type base layer 30 is formed. Arsenic is self-alignedly implanted to the gate electrode 33 with 60 keV and impurity concentration of 2E15 atom/cm², whereby the emitter feed layer 29 is formed. FIG. 7 is a chart illustrating an impurity concentration distribution at a portion of B-B′ near the surface where an NPN junction is formed.

A vertical axis of this graph indicates the impurity concentration (/cm³), while a horizontal axis indicates a distance (um). It can be confirmed from this graph that an NPN bipolar transistor with a base length of about 250 nm is present. This NPN bipolar transistor is adjusted such that the concentration of each of the emitter region, the base region, and the collector region becomes smaller in the order from the emitter, the base, and the collector. When performance of this bipolar transistor is calculated by a device simulation, hfe is 29, which means that this bipolar transistor performs an amplifying operation without any trouble.

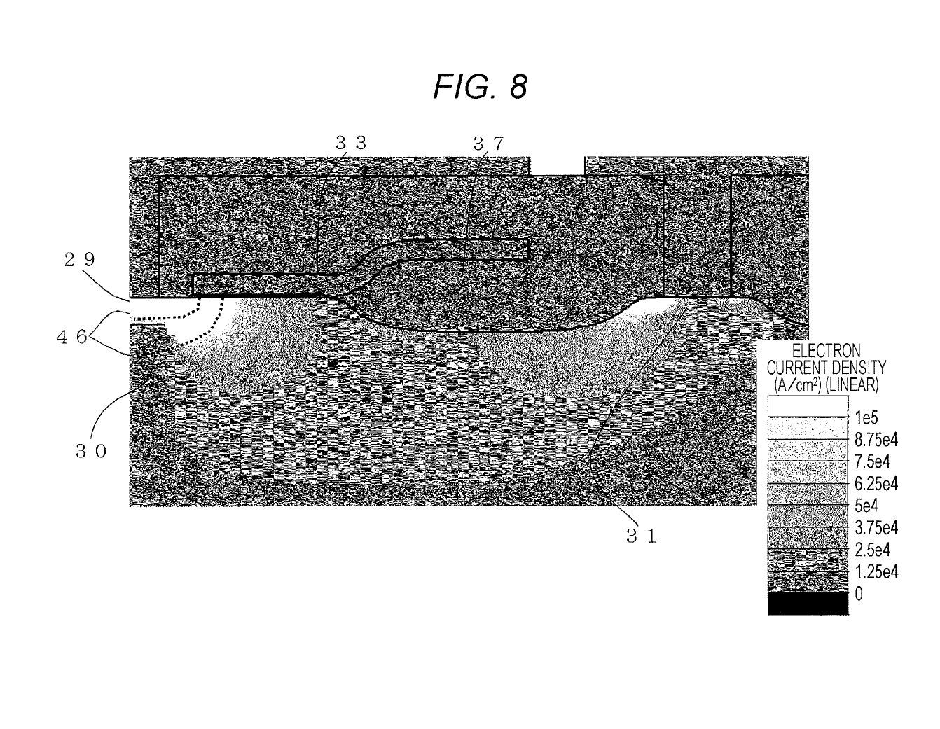

FIG. 8 is a chart illustrating an electron current profile when Vc is 1 V, and Vb is increased. It can be confirmed from this chart that electron flows from the emitter to the collector, so that the bipolar transistor performs an amplifying operation.

### Second Embodiment

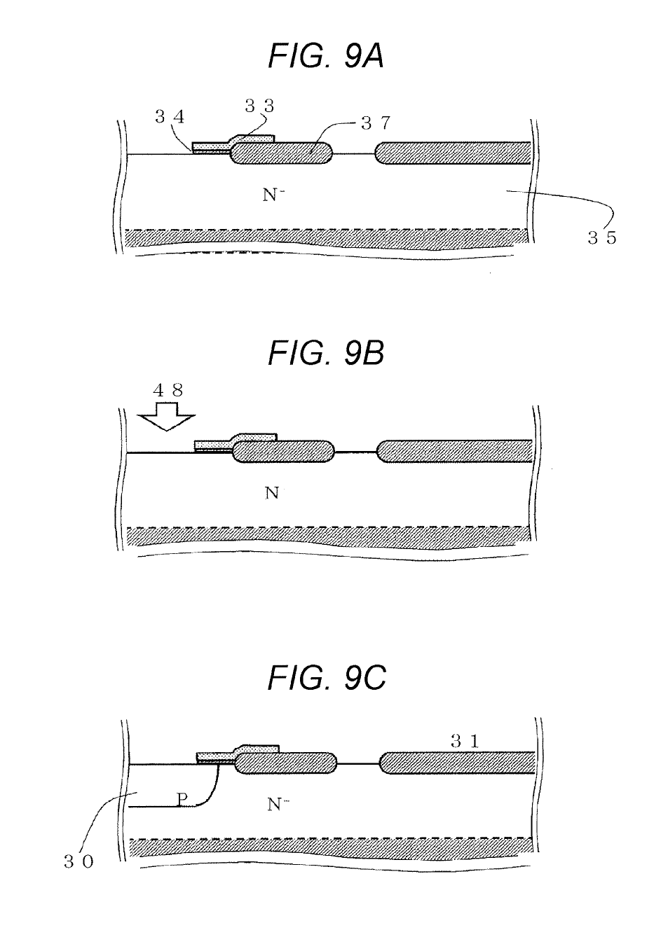

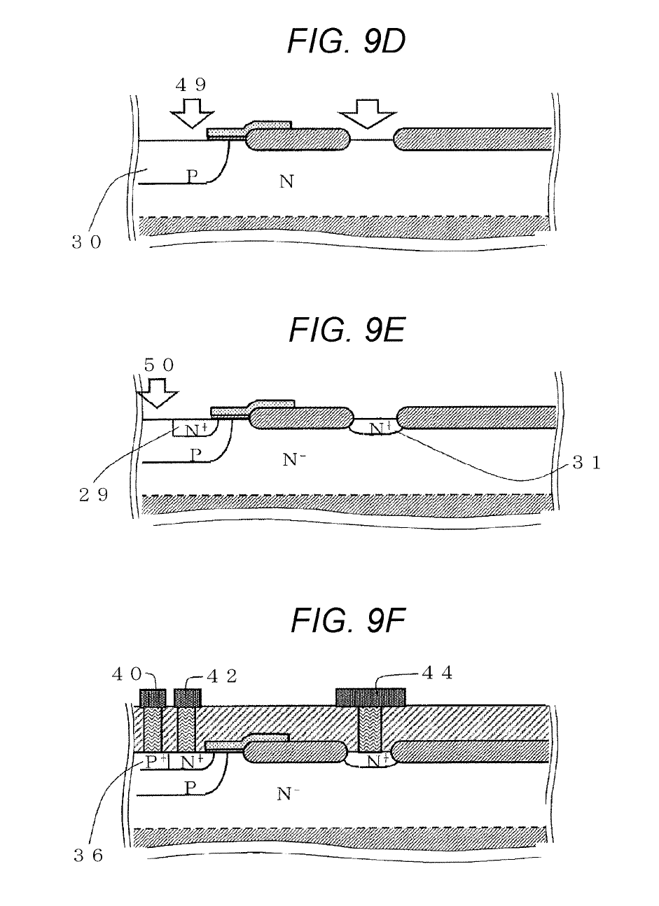

FIGS. 9A to 9F are each a process flow illustrating a manufacturing method of a lateral bipolar transistor according to a second embodiment of the present invention.

Firstly, a gate oxide film 34 and a gate electrode 33 are patterned on a surface of a semiconductor substrate having an N-type drift layer 35 as illustrated in FIG. 9A. Then, an impurity of boron forming a P-type base layer is self-alignedly implanted, as indicated by 48, to the gate electrode 33 as illustrated in FIG. 9B. The P-type base layer 30 is formed by applying a thermal load as illustrated in FIG. 9C. An impurity of arsenic forming an N-type emitter layer and an N-type collector layer is self-alignedly implanted, as indicated by 49, to the gate electrode 33 as illustrated in FIG. 9D. An impurity of boron fluoride forming a P-type base feed layer is implanted, as indicated by 50, as illustrated in FIG. 9E. After the application of a thermal load, plugs and electrodes are formed, whereby a lateral bipolar transistor having a base electrode 40, an emitter electrode 42, and a collector electrode 44 is completed, as illustrated in FIG. 9F.

### Third Embodiment

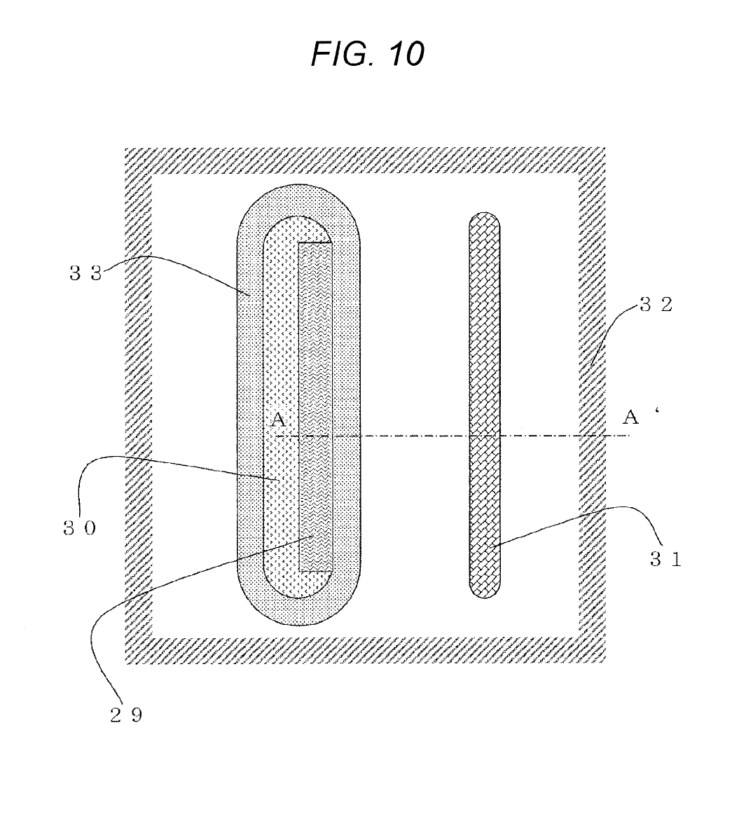

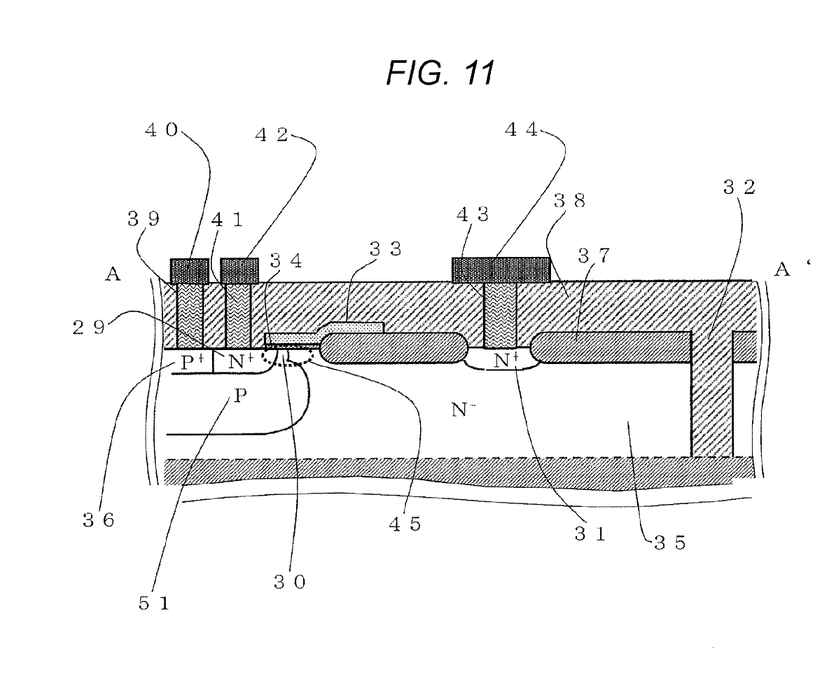

FIG. 10 is a plan view illustrating a device structure of a lateral bipolar transistor according to a third embodiment of the present invention, and FIG. 11 is a sectional view (sectional view taken along a line A-A′ in FIG. 10) illustrating the device structure of the lateral bipolar transistor according to the third embodiment of the present invention.

A field oxide film 37, a gate oxide film 34, and a gate electrode 33 are selectively formed on a surface of a semiconductor substrate having an N-type drift layer 35. An impurity is implanted through the gate electrode 33 and is thermally diffused, whereby a P-type base feed connection region 51 is self-alignedly formed. Similarly, an impurity is implanted in a region, shallower than the P-type base feed connection region 51, via the gate electrode 33, and is thermally diffused, whereby the P-type base layer 30 is self-alignedly formed. Similarly, an impurity is implanted via the gate electrode 33 and is thermally diffused, whereby an emitter feed layer 29 is self-alignedly formed. A base feed layer 36 is formed at a position contacting the emitter feed layer 29. A collector feed layer 31 is also formed at the side opposite to this region across the field oxide film 37.

A base electrode 40 is formed on the base feed layer 36 via a base plug 39, an emitter electrode 42 is formed on the emitter feed layer 29 via an emitter plug 41, and a collector electrode 44 is formed on the collector feed layer 31 via a collector plug 43. Thus, a lateral bipolar transistor to which the present invention is applied is formed.

In the present embodiment, the base is formed by two impurity implantations, whereby the P-type base layer 30 having higher concentration and shorter base width than the base region in the first embodiment is formed.

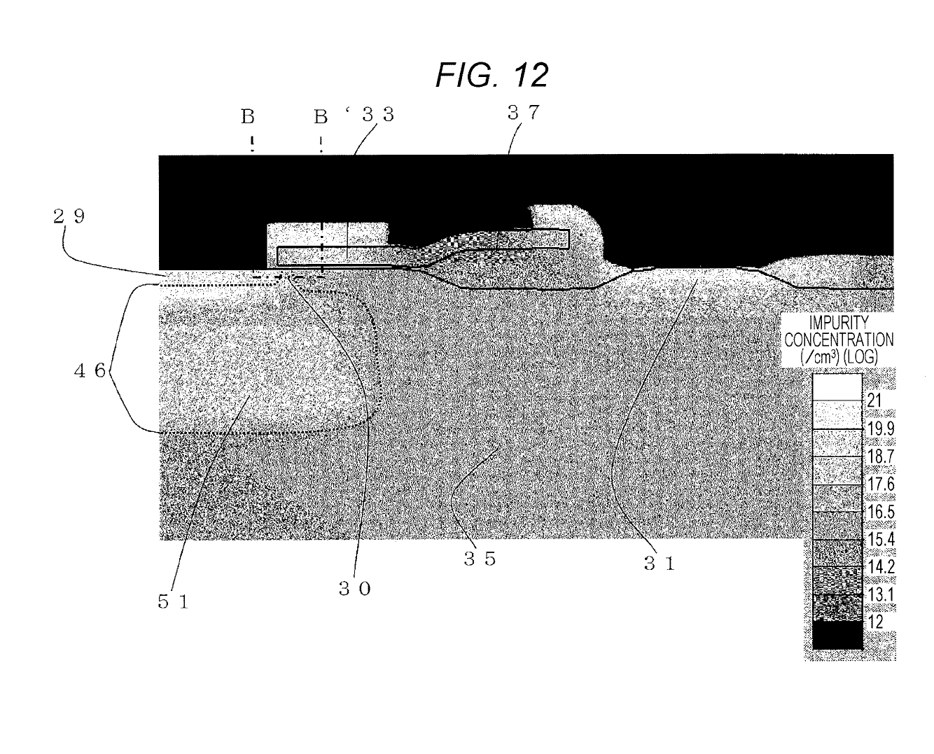

FIG. 12 illustrates a sectional structure of a lateral bipolar transistor, which is formed by a process simulation and to which the present invention is applied. Boron is self-alignedly implanted to the gate electrode 33 with acceleration energy of 300 keV and impurity concentration of 1.5E13 atom/cm², and is thermally diffused, whereby the P-type base feed connection region 51 is formed. Boron is self-alignedly and obliquely implanted to the gate electrode 33 with acceleration energy of 30 keV and impurity concentration of 1E13 atom/cm², and is thermally diffused, whereby the P-type base layer 30 is formed.

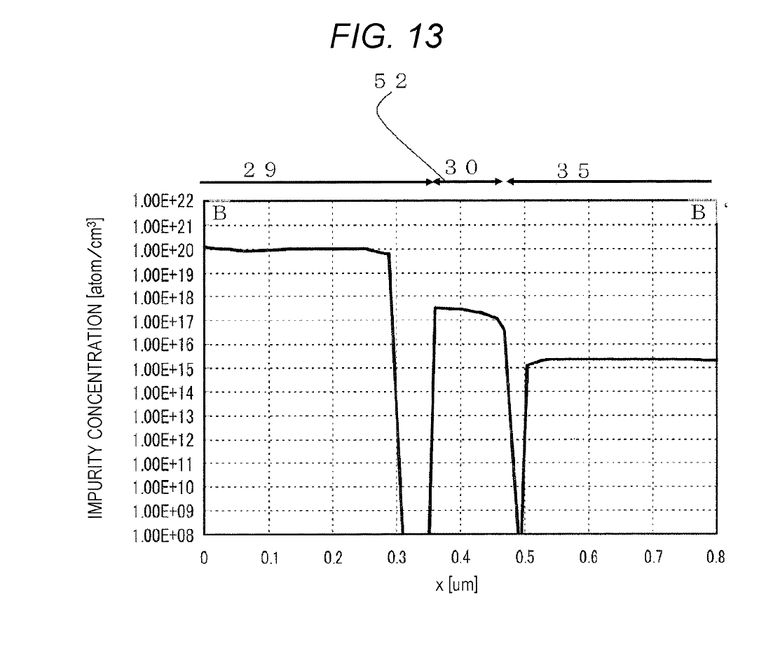

Arsenic is self-alignedly implanted to the gate electrode 33 with 60 keV and impurity concentration of 2E15 atom/cm², whereby the emitter feed layer 29 is formed. FIG. 13 is a chart illustrating an impurity concentration distribution at a portion of B-B′ near the surface where an NPN junction is formed. A vertical axis of this graph indicates the impurity concentration (/cm³), while a horizontal axis indicates a distance (um). It can be confirmed from this graph that an NPN bipolar transistor with a base length of about 100 nm is present. This NPN bipolar transistor is adjusted such that the concentration of each of the emitter region, the base region, and the collector region becomes smaller in the order from the emitter, the base, and the collector.

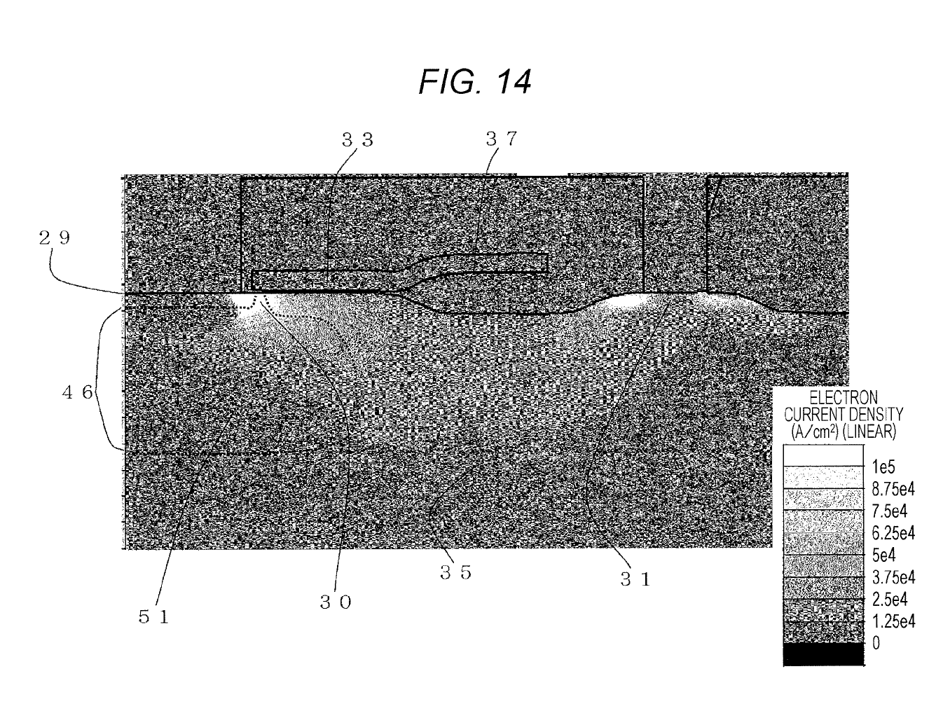

When performance of this bipolar transistor is calculated by a device simulation, hfe is 41, which means that this bipolar transistor operates with an amplification factor higher than that in the first embodiment. FIG. 14 is a chart illustrating an electron current profile when Vc is 1 V, and Vb is increased. It can be confirmed from this chart that electron flows from the emitter to the collector, so that the bipolar transistor performs an amplifying operation.

### Fourth Embodiment

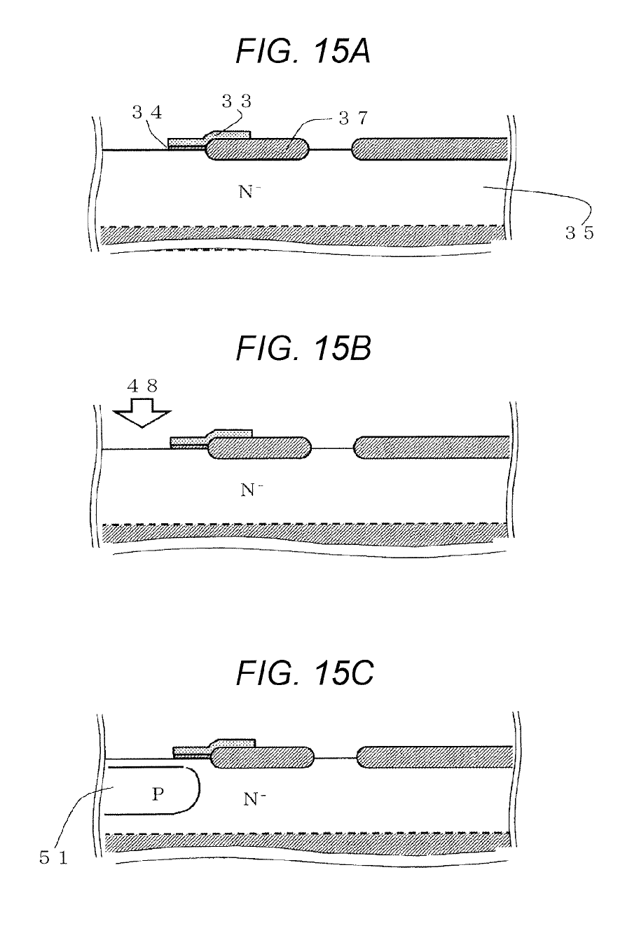

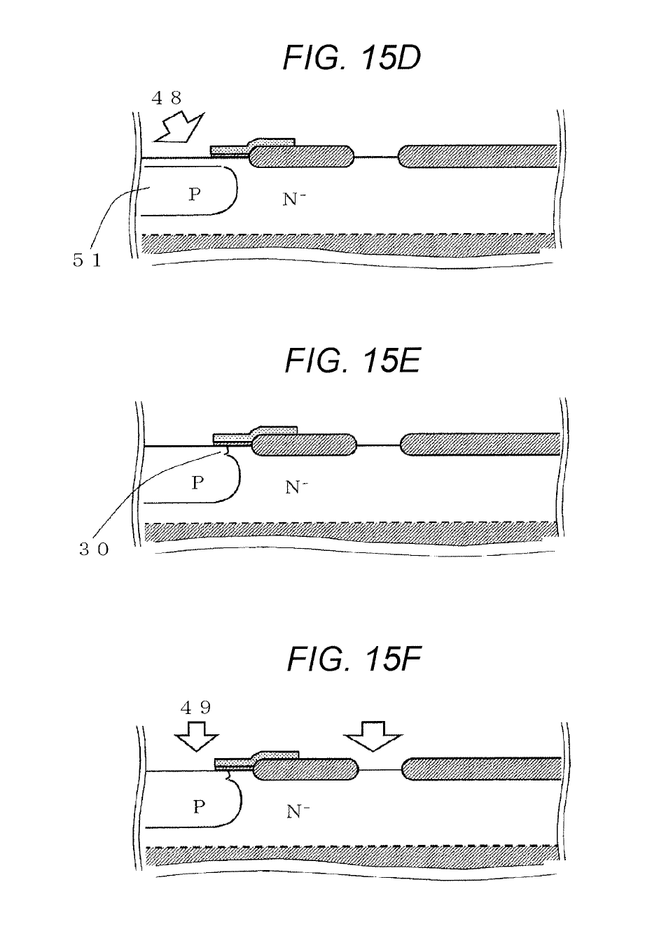

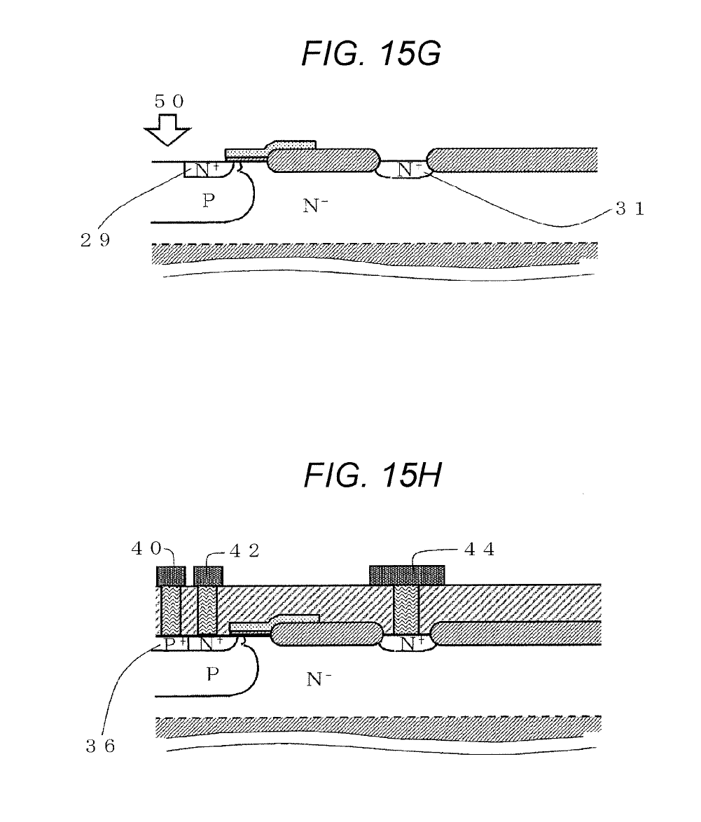

FIGS. 15A to 15H are each a process flow illustrating a manufacturing method of a lateral bipolar transistor according to a fourth embodiment of the present invention.

Firstly, a gate oxide film 34 and a gate electrode 33 are patterned on a surface of a semiconductor substrate having an N-type drift layer 35 as illustrated in FIG. 15A. Then, an impurity of boron forming a P-type base feed connection layer is self-alignedly implanted, as indicated by 48, to the gate electrode 33 as illustrated in FIG. 15B. The P-type base feed connection region 51 is formed by applying a thermal load as illustrated in FIG. 15C. An impurity of boron forming a P-type base layer is self-alignedly implanted, as indicated by 48, to the gate electrode 33 as illustrated in FIG. 15D. In this case, the impurity may be implanted from an oblique direction with respect to a vertical line at tens of degrees in order to optimize the base length. The P-type base layer 30 is formed by applying a thermal load as illustrated in FIG. 15E. An impurity of arsenic forming an N-type emitter layer and an N-type collector layer is self-alignedly implanted, as indicated by 49, to the gate electrode 33 as illustrated in FIG. 15F. An impurity of boron fluoride forming a P-type base layer is implanted, as indicated by 50, as illustrated in FIG. 15G. After the application of a thermal load, plugs and electrodes are formed, whereby a lateral bipolar transistor having a base electrode 40, an emitter electrode 42, and a collector electrode 44 is completed, as illustrated in FIG. 15H.

### Fifth Embodiment

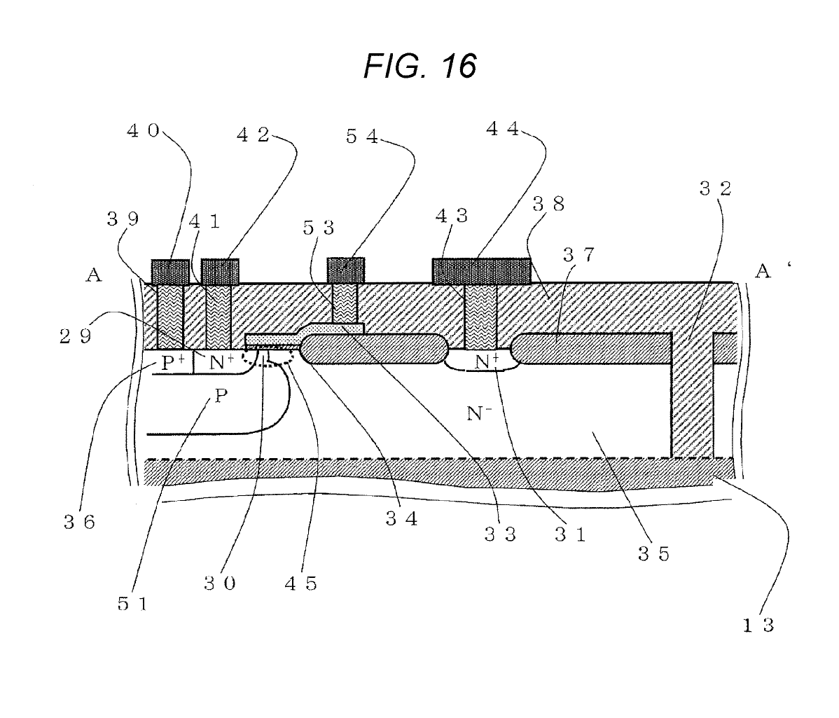

FIG. 16 is a sectional view (sectional view taken along a line same as lines A-A′ in FIGS. 4 and 10) illustrating a device structure of a lateral bipolar transistor according to the fifth embodiment of the present invention.

With respect to the structure in the third embodiment, the bipolar transistor according to the present embodiment uses the gate electrode 33 as a voltage control terminal. Thus, the bipolar transistor according to the present embodiment includes four terminals that are the base electrode 40, the emitter electrode 42, the collector electrode 44, and the gate electrode 33.

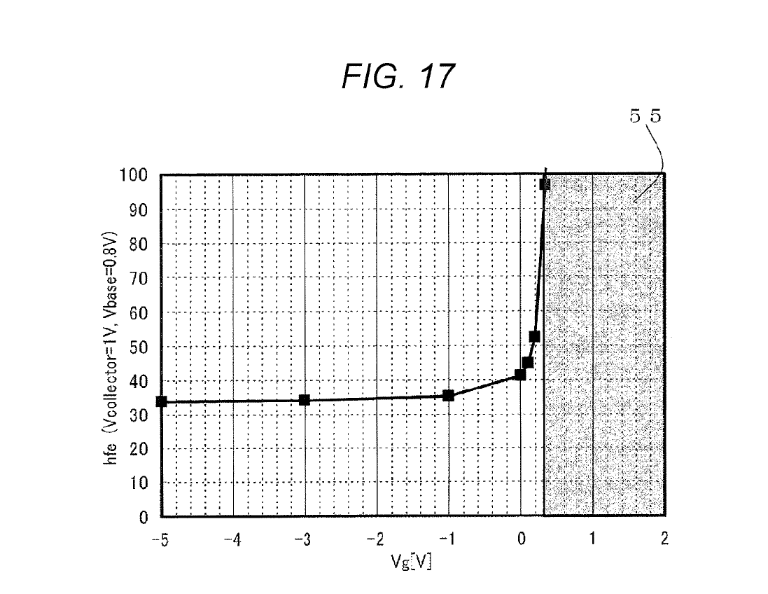

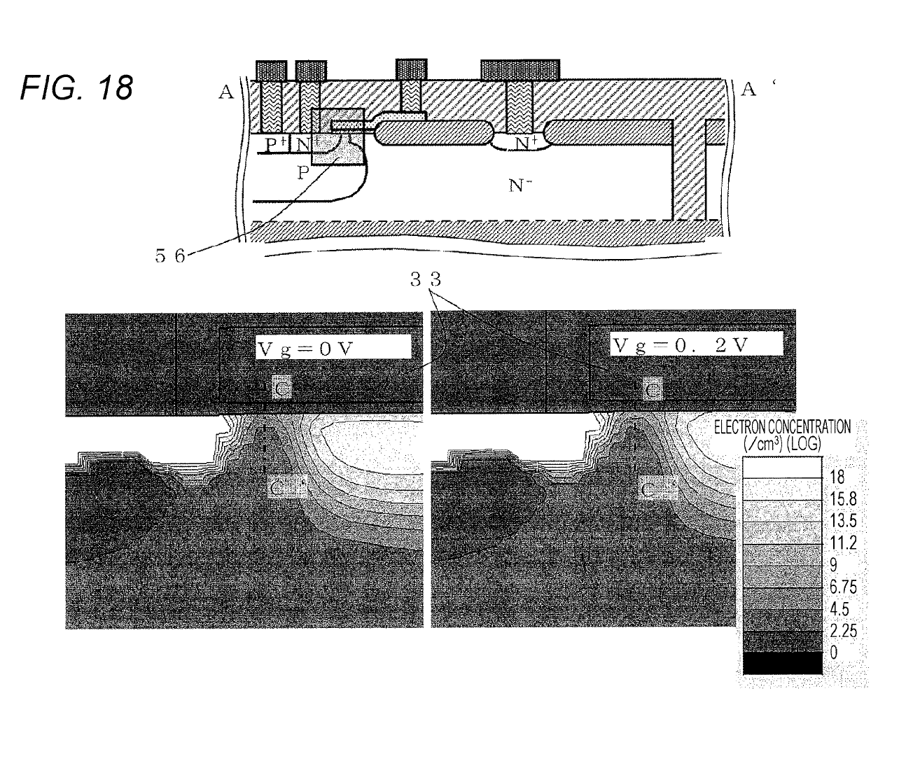

FIG. 17 illustrates dependency of hfe to a gate potential (Vg), calculated by a device simulation. When the gate potential is increased to 0.2 V from 0 V, the hfe increases to 52 from 41. FIG. 18 illustrates a cross-section of the device, and an electron concentration profile observed when the gate potential is changed.

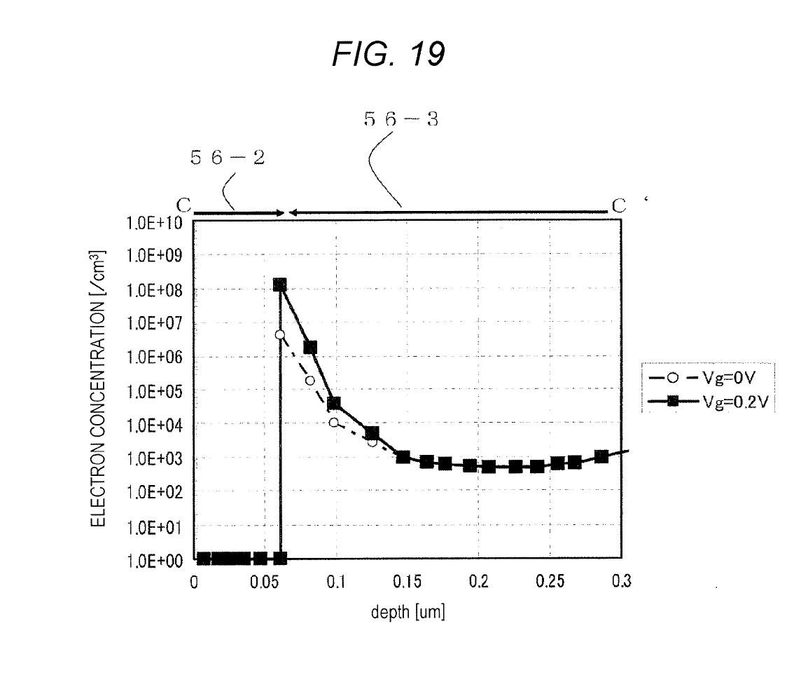

The correlation between the electron concentration and depth on the section along a C-C′ is as illustrated in FIG. 19. The electron concentration in the base region increases with the increase in the gate potential. This shows that an electric field formed by the gate potential increases the electron injection efficiency from the emitter to the base. It is considered that, with this, the electron injection efficiency to the collector also increases, whereby the hfe increases. When the gate potential is increased 0.2 V or more, the hfe further increases, but the base region becomes an inversion layer, as understood from FIG. 17. Therefore, leak occurs between the collector and the emitter, resulting in that controllability of the transistor is lost.

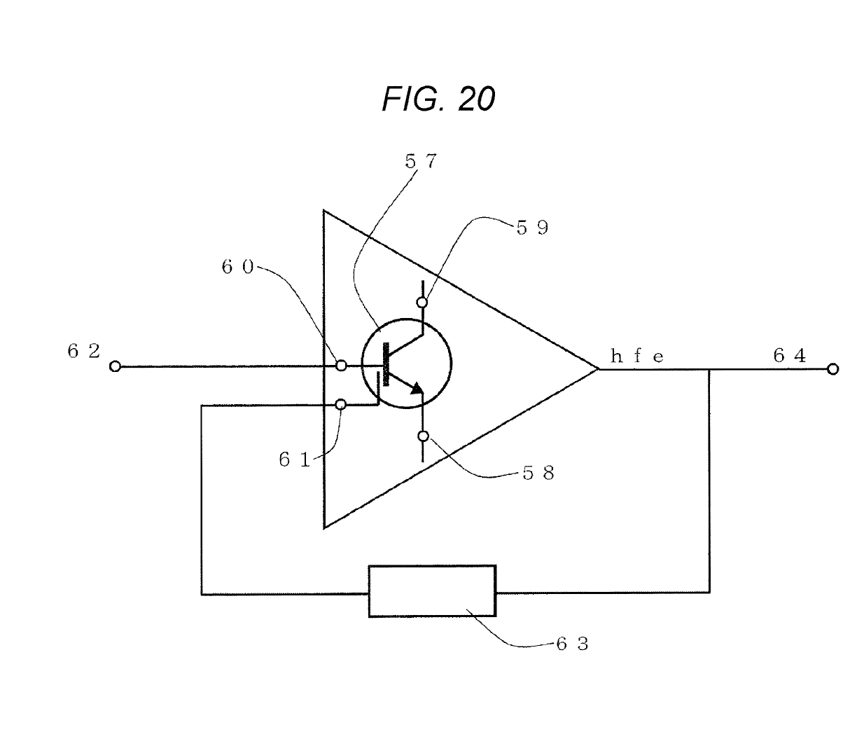

As described above, the hfe can be controlled by adding a gate terminal. When the bipolar transistor according to the present invention is combined to a feedback circuit illustrated in FIG. 20, a manufacturing variation is suppressed, and stable gain is obtained.

### LIST OF REFERENCE NUMBERS

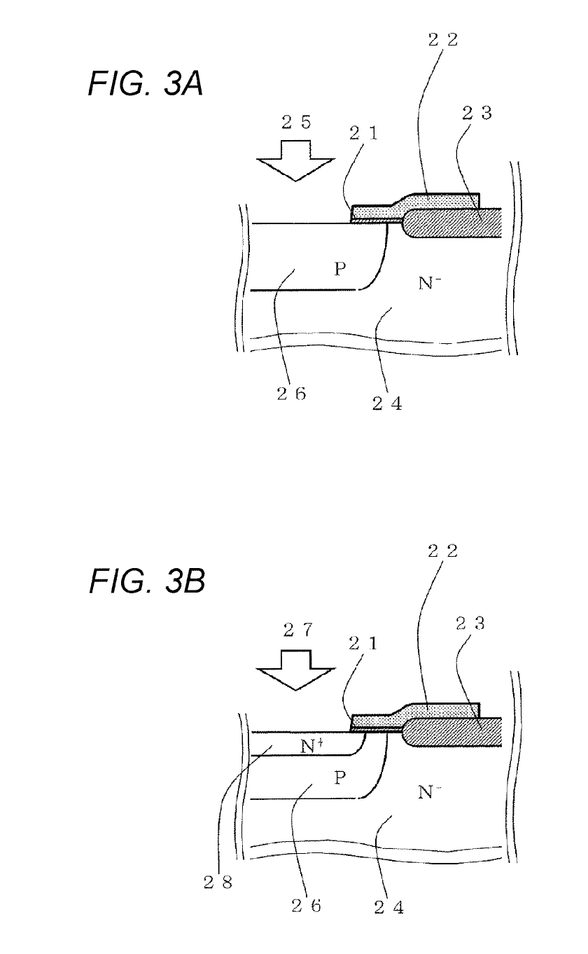

1: low voltage power source Vcc
2: high voltage power source VH
3: load
4: NPN bipolar transistor
5: GND terminal
6: base resistor
7: digital control circuit
8: PNP bipolar transistor
12: N-type collector feed region
13: buried oxide film layer
14: oxide film layer
18: LOCOS (local oxidation of silicon) region
21: gate oxide film layer
22: gate electrode
23: field oxide film layer
24: N-type drift layer
25: a P-type impurity is self-alignedly implanted, as indicated by 25 in FIG. 3A
26: P-type impurity region
27: a N-type impurity is self-allegedly implanted, as indicated by 27 in FIG. 3B
28: N-type source layer
29: N-type emitter feed layer
30: P-type base layer
31: N-type collector feed layer
32: LOCOS (local oxidation of silicon) region
33: gate conductor
34: gate oxide film
35: N-type drift layer
36: P-type base feed layer
37: field oxide film
38: insulating film layer
39: base plug
40: base conductor
41: emitter plug
42: emitter conductor
43: collector plug
44: collector conductor
45: NPN bipolar transistor forming region 29, 30, 35, and
47 N-type emitter feed layer, P-type base layer, N-type collector drift layer and “base length” (250 nm in FIG. 7)
46: P-N junction boundary lines
48: a P-type impurity is self-alignedly implanted, as indicated by 48 in FIG. 9B
49: an N-type impurity is self-alignedly implanted, as indicated by 49 in FIG. 9D
50: a P-type impurity is self-alignedly implanted, as indicated by 50 in FIG. 9E
51: P-type base feed connecting region in FIG. 14 and FIG.
15C
52: base length is 100 nm in FIG. 13
53: gate plug
54: gate conductor
55: hatching portion 55 is a region that a reverse layer is formed on the base layer 30, and leak current between collector and emitter is increasing in the region in FIG. 17.
56: simulation region of electron concentration value in FIG. 18.
56-2: region of gate conductor and gate insulator film
56-3: region of base layer
57: bipolar transistor of the present invention
58: emitter terminal
59: collector terminal
60: base terminal
61: gate terminal
62: input terminal
63: load for gain regulation
64: output terminal

What is claimed is:

1. A lateral bipolar transistor comprising:
a semiconductor substrate;
a gate oxide film and a gate electrode, which are formed on a surface of the semiconductor substrate;
a collector region formed apart from the gate electrode with a distance, and having a feed region of a first conductive type;
an emitter region formed in the vicinity of the gate oxide film in a horizontal direction at a side opposite to the collector region across the gate electrode, and having a feed region of a first conductive type; and
a base region of a second conductive type formed below the gate oxide film and having a feed region that is located close to the emitter feed region, wherein
the emitter region, the base region, and the collector region are formed in the horizontal direction.

2. The lateral bipolar transistor according to claim 1, wherein a concentration of an impurity in the collector region, the base region, and the emitter region becomes smaller in the order from the collector region, the base region, and the emitter region at a portion below the gate oxide film and in the vicinity of the surface of the semiconductor region.

3. The lateral bipolar transistor according to claim 1, wherein
a field oxide film thicker than the gate oxide film is selectively formed on the surface of the semiconductor substrate,
one end of the gate electrode runs over the field oxide film, and
the feed region included in the collector region is provided in the vicinity of the field oxide film.

4. The lateral bipolar transistor according to claim 1, wherein the gate electrode is used as an independent voltage control terminal, and the lateral bipolar transistor can be controlled by four terminals which are the voltage control terminal, a collector terminal connected to the collector region, a base terminal connected to the base region, and an emitter terminal connected to the emitter region.

5. The lateral bipolar transistor according to claim 1, wherein
a voltage less than a voltage by which an inversion layer is formed in the base region is applied to the gate terminal.

6. The lateral bipolar transistor according to claim 1, wherein the semiconductor substrate is an SOI substrate.

7. A method of manufacturing a lateral bipolar transistor comprising:
selectively forming a gate oxide film and a gate electrode on a surface of a semiconductor region present on a semiconductor substrate;
forming a collector region, having a feed region of a first conductive type, apart from the gate electrode with a predetermined distance; and
self-alignedly forming a base region via the gate electrode, and self-alignedly forming an emitter region, having a feed region of a first conductive type, to the gate electrode in the vicinity of the gate oxide film, in a region horizontal to the collector region across the gate electrode.

8. The manufacturing method of a lateral bipolar transistor according to claim 7, wherein a concentration of an impurity in the collector region, the base region, and the emitter region becomes smaller in the order from the collector region, the base region, and the emitter region at a portion below the gate oxide film and in the vicinity of the surface of the semiconductor region.

9. The manufacturing method of a lateral bipolar transistor according to claim 7, wherein the base region below the gate oxide film is formed by performing at least two impurity implantations to the gate electrode at a deep position and a shallow position from the surface of the semiconductor in a self-aligned manner.

10. The manufacturing method of a lateral bipolar transistor according to claim 7, further comprising:
selectively forming a field oxide film, thicker than the gate oxide film, on the surface of the semiconductor region, wherein
one end of the gate electrode runs over the field oxide film, and
the feed region included in the collector region is provided in the vicinity of the field oxide film.

11. The manufacturing method of a lateral bipolar transistor according to claim 7, wherein the gate electrode is used as an independent voltage control terminal, and an electrode structure that can be controlled by four terminals which are the voltage control terminal, a collector terminal connected to the collector region, a base terminal connected to the base region, and an emitter terminal connected to the emitter region is formed.

12. The manufacturing method of a lateral bipolar transistor according to claim 7, wherein the semiconductor substrate is an SOI substrate.
